(19) United States
(12) Patent Application Publication
(10) Pub. No.: US 2025/0285857 A1
(43) Pub. Date: Sep. 11, 2025

(54) METHODS OF DEPOSITING SILICON NITRIDE

(71) Applicant: Applied Materials, Inc., Santa Clara, CA (US)

(72) Inventors: Hanhong Chen, Milpitas, CA (US); Hao Zhang, San Jose, CA (US); Chi-Chou Lin, San Jose, CA (US)

(73) Assignee: Applied Materials, Inc., Santa Clara, CA (US)

(21) Appl. No.: 19/070,711

(22) Filed: Mar. 5, 2025

Related U.S. Application Data
(60) Provisional application No. 63/562,431, filed on Mar. 7, 2024.

(51) Int. Cl. H01L 21/02; C23C 16/34; C23C 16/455; H01J 37/32

(52) U.S. Cl. CPC H01L 21/02274; C23C 16/345; C23C 16/45542; H01L 21/0217; H01L 21/0228; H01J 37/32192; H01J 2237/3321

(57) ABSTRACT

Methods of depositing silicon nitride (SiₓN_{y}) films by plasma-enhanced atomic layer deposition (PEALD) are disclosed. Exemplary methods include exposing a substrate in a semiconductor processing chamber to a silicon-containing precursor; exposing the substrate to a first plasma including nitrogen (N₂); exposing the substrate to a second plasma including one or more of ammonia (NH₃) or hydrogen (H₂); and exposing the substrate to a third plasma including nitrogen (N₂).

### CROSS-REFERENCE TO RELATED APPLICATIONS

This application claims priority to U.S. Provisional Application No. 63/562,431, filed Mar. 7, 2024, the entire disclosure of which is incorporated by reference herein.

### TECHNICAL FIELD

Embodiments of the disclosure generally relate to the field of semiconductor device manufacturing. More particularly, embodiments of the disclosure are directed to methods of depositing silicon nitride (SiₓN_{y}) films by plasma-enhanced atomic layer deposition (PEALD).

### BACKGROUND

Silicon nitride (SiₓN_{y}) films have attractive dielectric material properties. These films have been proposed and tested for applications from front-end of line (FEOL) to back-end of line (BEOL) processes and parts of semiconductor and microelectronic devices. Generally, FEOL refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

Low temperature, e.g., less than or equal to 600° C., atomic layer deposition (ALD) of silicon nitride (SiₓN_{y}) films are used in many semiconductor applications. Without intending to be bound by any particular theory, it is thought that many of these lower temperature applications are deposited by plasma-enhanced ALD (PEALD) due to poor film quality by low temperature thermal processes, e.g., a thermal ALD process.

PEALD film quality varies based on the surface (e.g., substrate) on which the film is deposited. In particular, it has been found that PEALD film quality varies based on the geometry of the substrate, and areas that are harder to treat with plasma species may receive less plasma treatment and have poorer film quality. PEALD may also utilize a single plasma exposure to perform both a silicon-containing precursor-nitrogen reaction step to form a film and a film densification step.

Unfortunately, the combination of the reaction step and the densification step leads to the incorporation of reaction byproducts into the films as impurities, thereby causing lower film quality. Further, the plasma species may strip hydrogen from the substrate surface, thereby reducing sites for further precursor adsorption and reducing growth rate per cycle (GPC).

For example, current PEALD approaches, e.g., (1) exposure to silicon-containing precursor, purge, exposure to thermal ammonia (NH₃), followed by nitrogen (N₂) plasma, or (2) exposure to silicon-containing precursor, purge, exposure to ammonia (NH₃) plasma, and purge, may independently produce films of poor quality and reduced GPC for advancing semiconductor manufacturing requirements.

Accordingly, there is a need for improved PEALD of SiₓN_{y} that provide increased film growth rate and improved film quality.

### SUMMARY

One or more embodiments of the disclosure are directed to a method of depositing a silicon nitride (SiₓN_{y}) film. The method comprises exposing a substrate in a semiconductor processing chamber to a silicon-containing precursor; exposing the substrate to a first plasma including nitrogen (N₂); exposing the substrate to a second plasma including one or more of ammonia (NH₃) or hydrogen (H₂); and exposing the substrate to a third plasma including nitrogen (N₂).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the present disclosure and are therefore not to be considered limiting of its scope, for the disclosure may admit to other equally effective embodiments.

FIG. 1 illustrates a process flow diagram of a method of depositing a silicon nitride (SiₓN_{y}) film according to one or more embodiments of the disclosure;

FIG. 2 illustrates a cross-sectional schematic view of a substrate according to one or more embodiments of the disclosure;

FIG. 3A illustrates a cross-sectional schematic view of a substrate according to one or more embodiments of the disclosure;

FIG. 3B illustrates a cross-sectional schematic view of a substrate according to one or more embodiments of the disclosure;

FIG. 4 illustrates a schematic representation of a processing tool comprising a modular high-frequency emission source with a plasma showerhead assembly that comprises a plurality of applicators according to one or more embodiments of the disclosure;

FIG. 5 illustrates a block diagram of a high-frequency emission module according to one or more embodiments of the disclosure;

FIG. 6 illustrates a schematic exploded perspective view of the plasma showerhead assembly of FIG. 4 according to one or more embodiments of the disclosure; and

FIG. 7 illustrates a cross-sectional view of a processing tool according to one or more embodiments.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as a metallic material, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., hydrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. As used herein, the term “thermal process(es)” refers to a deposition technique that does not involve the use of plasma. As used herein, the term “plasma” refers to a composition have ionically charged species and uncharged neutral and radical species.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

Plasma-enhanced atomic layer deposition (PEALD) methods add a plasma exposure to traditional ALD methods. In some PEALD methods, a nitrogen source is provided as the plasma. The primary benefit of PEALD methods is the relatively low substrate temperature, e.g., less than or equal to 600° C., during processing.

Embodiments of the disclosure are directed to methods of depositing silicon nitride (SiₓN_{y}) films by plasma-enhanced atomic layer deposition (PEALD). The skilled artisan will recognize that the use of a molecular formula such as SiₓN_{y} does not imply specific stoichiometric relation between the elements but merely the identity of the major components of the film. In some embodiments, the major composition of the specified film (i.e., the sum of the atomic percent of the specified atoms) is greater than or equal to about 95%, 98%, 99%, 99.5%, or 99.9% of the film, on an atomic basis. In one or more embodiments, the silicon nitride (SiₓN_{y}) film comprises Si₃N₄.

Embodiments of the disclosure advantageously provides methods of depositing a silicon nitride (SiₓN_{y}) film at an increased growth rate per cycle (GPC). Some embodiments advantageously provide methods of depositing a silicon nitride (SiₓN_{y}) film having improved film quality. Some embodiments advantageously provide methods of depositing improved quality silicon nitride (SiₓN_{y}) films that are useful for FEOL and BEOL processes and parts.

There are multiple metrics used to measure SiₓN_{y} film quality. One of the most common metrics used to measure SiₓN_{y} film quality is the wet etch rate of the deposited film under dilute hydrofluoric (HF) acid etch solution, such as dilute HF 100:1. Embodiments of the disclosure advantageously provide a SiₓN_{y} film that has a reduced etch amount in Angstroms (Å) using dilute HF 100:1, which represents an improved wet etch rate, compared to a current PEALD approaches.

Additional embodiments of the disclosure provide a plasma showerhead assembly, e.g., an assembly, for a processing tool. In one or more embodiments, the assembly comprises a conductive plate and a dielectric faceplate.

In one or more embodiments, the conductive plate includes a first surface and a second surface opposite to the first surface defining a conductive plate thickness, a plurality of resonator openings extending from the first surface through the conductive plate to the second surface of the conductive plate, gas channels within the conductive plate thickness, a plurality of conductive plate gas openings on the second surface of the conductive plate in fluid communication with the gas channels within the conductive plate thickness.

In one or more embodiments, the dielectric faceplate comprises a first surface and a second surface opposite to the first surface defining a dielectric faceplate thickness, a plurality of dielectric resonator protruding from the first surface and configured so that the resonators fit into the plurality of the resonator openings of the conductive plate when assembled, each resonator having a geometric center; and a plurality of dielectric faceplate gas openings extending through the dielectric faceplate thickness.

In one or more embodiments, the assembly comprises a plurality of o-rings surrounding the conductive plate gas openings and the dielectric faceplate gas openings, wherein the dielectric faceplate gas openings are in fluid communication with the conductive plate gas openings and the o-rings are configured to seal the dielectric faceplate gas openings and the conductive plate gas openings from atmospheric pressure.

The assembly described herein is a microwave plasma source that may be used to generate a microwave plasma of any of the plasma compositions described herein. Advantageously, the energy of the microwaves can be tuned low enough that it does not substantially damage dielectric materials (e.g., no plasma and/or low temperature). Further, the disclosed methods are self-limiting by only affecting the SiₓN_{y} film and not the other layers, such as a dielectric layer, in the structures.

The embodiments of the disclosure are described by way of the Figures, which illustrate processes, substrates, and apparatuses in accordance with one or more embodiments of the disclosure. The processes and resulting substrates shown are merely illustrative of the disclosed processes, and the skilled artisan will recognize that the disclosed processes are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

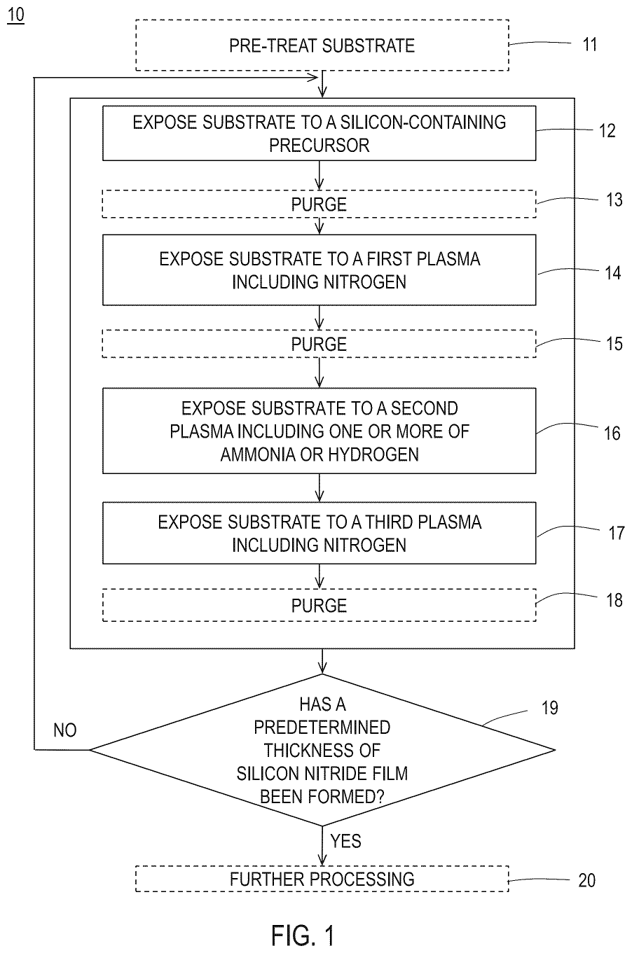

FIG. 1 illustrates a process flow diagram of a method 10 of depositing a silicon nitride (SiₓN_{y}) film 54. The method 10 begins by optionally pre-treating the substrate 50 (operation 11). The pre-treatment can be any suitable pre-treatment known to the skilled artisan. Suitable pre-treatments include, but are not limited to, pre-heating, cleaning, soaking, or native oxide removal, as examples.

The method 10 of one or more embodiments comprises depositing the silicon nitride (SiₓN_{y}) film 54 by PEALD. In one or more embodiments, the method 10 comprises exposing the substrate 50 to a silicon-containing precursor (operation 12); optionally purging the substrate 50 (operation 13); exposing the substrate 50 to a first plasma including nitrogen (N₂) (operation 14); optionally purging the substrate 50 (operation 15); exposing the substrate 50 to a second plasma including one or more of ammonia (NH₃) or hydrogen (H₂) (operation 16); exposing the substrate 50 to a third plasma including nitrogen (N₂) (operation 17); and optionally purging the substrate 50 (operation 18). In one or more embodiments of FIG. 1, the dashed lines are used to denote that the stated operation is optional.

The use of ordinals such as “first,” “second,” and “third” to describe the specific plasmas, e.g., the first plasma, the second plasma, or the third plasma, does not necessarily imply an order of formation, unless the context specifically indicates otherwise. A substrate may be exposed to a “second” plasma before the substrate is exposed to a “first” plasma. The ordinals are used for descriptive purposes when referring to the Figures.

In some embodiments, the substrate is exposed to the silicon-containing precursor at operation 12, followed by exposure to the first plasma including nitrogen (N₂) at operation 14, followed by exposure to the second plasma including one or more of ammonia (NH₃) or hydrogen (H₂) at operation 16, followed by exposure to the third plasma including nitrogen (N₂) at operation 17.

As used herein, “exposing the substrate to a first plasma,” e.g., operation 14, may be interchangeably referred to as a “first plasma exposure,” “exposing the substrate to a second plasma,” e.g., operation 16, may be interchangeably referred to as a “second plasma exposure,” and “exposing the substrate to a third plasma,” e.g., operation 17, may be interchangeably referred to as a “third plasma exposure.”

The method 10 continues to decision point 19. At decision point 19, the substrate 50 is evaluated to determine whether or not the silicon nitride (SiₓN_{y}) film 54 has reached a predetermined thickness or a predetermined number of cycles have been performed. As used herein, each “cycle” refers to each iteration in which the method 10 is performed to deposit the silicon nitride (SiₓN_{y}) film to a predetermined thickness. If the conditions are met e.g., the answer to decision point 19 is “YES,” the method 10 continues to operation 20 for further processing. If the conditions are not met, e.g., the answer to decision point 19 is “NO,” the method 10 returns to optional operation 11, or to operation 12. One or more embodiments of the method 10 comprise repeating one or more operations of the method to deposit the silicon nitride (SiₓN_{y}) film 54 to a predetermined thickness.

In one or more embodiments, the method 10 comprises operation 11, operation 12, operation 13, operation 14, operation 15, operation 16, operation 17, operation 18, decision point 19, and operation 20. In one or more embodiments, the method 10 consists essentially of operation 11, operation 12, operation 13, operation 14, operation 15, operation 16, operation 17, operation 18, decision point 19, and operation 20. In one or more embodiments, the method 10 consists of operation 11, operation 12, operation 13, operation 14, operation 15, operation 16, operation 17, operation 18, decision point 19, and operation 20.

The silicon-containing precursor may be any suitable precursor that includes silicon. In some embodiments, the silicon-containing precursor includes, but is not limited to, one or more of a silane (SiₓH_{y}), a chlorosilane (SiₓH_{y}Cl_{z}), or an iodosilane (SiₓH_{y}I_{z}). In some embodiments, the silicon-containing precursor includes one or more of silane (SiH₄), disilane (Si₂H₆), chlorosilane (H₃SiCl), dichlorosilane (H₂SiCl₂), trichlorosilane (HSiCl₃), tetrachlorosilane (SiCl₄), iodosilane (H₃ISi), diiodosilane (H₂I₂Si), triiodosilane (HI₃Si), or tetraiodosilane (I₄Si). In some embodiments, the silicon-containing precursor includes bis(diethylamino)silane (BDEAS).

In one or more embodiments, the first plasma comprises nitrogen (N₂). In one or more embodiments, the first plasma consists essentially of nitrogen (N₂). In one or more embodiments, the first plasma consists of nitrogen (N₂).

In one or more embodiments, the first plasma comprises nitrogen (N₂) and argon (Ar). In one or more embodiments, the first plasma consists essentially of nitrogen (N₂) and argon (Ar). In one or more embodiments, the first plasma consists of nitrogen (N₂) and argon (Ar).

In one or more embodiments, the first plasma comprises nitrogen (N₂) and helium (He). In one or more embodiments, the first plasma consists essentially of nitrogen (N₂) and helium (He). In one or more embodiments, the first plasma consists of nitrogen (N₂) and helium (He).

Without intending to be bound by theory, it is thought that the first plasma comprising nitrogen (N₂) densifies the silicon nitride (SiₓN_{y}) film by cross-linking the bonding between the silicon atoms from the silicon-containing precursor and reactive nitrogen species from the first plasma comprising nitrogen (N₂), e.g. nitrogen radicals and nitrogen ions. In one or more embodiments, the substrate 50 is purged after the first plasma exposure, prior to the second plasma exposure.

In one or more embodiments, the second plasma comprises one or more of ammonia (NH₃) or hydrogen (H₂). In one or more embodiments, the second plasma comprises ammonia (NH₃) and hydrogen (H₂). In one or more embodiments, the second plasma consists essentially of ammonia (NH₃) and hydrogen (H₂). In one or more embodiments, the second plasma consists of ammonia (NH₃) and hydrogen (H₂).

In one or more embodiments, the second plasma comprises ammonia (NH₃). In one or more embodiments, the second plasma consists essentially of ammonia (NH₃). In one or more embodiments, the second plasma consists of ammonia (NH₃). In one or more embodiments, the second plasma comprises hydrogen (H₂). In one or more embodiments, the second plasma consists essentially of hydrogen (H₂). In one or more embodiments, the second plasma consists of hydrogen (H₂).

In one or more embodiments, the second plasma comprises one or more of ammonia (NH₃) or hydrogen (H₂), and argon (Ar).

In one or more embodiments, the second plasma comprises ammonia (NH₃) and argon (Ar). In one or more embodiments, the second plasma consists essentially of ammonia (NH₃) and argon (Ar). In one or more embodiments, the second plasma consists of ammonia (NH₃) and argon (Ar).

In one or more embodiments, the second plasma comprises hydrogen (H₂) and argon (Ar). In one or more embodiments, the second plasma consists essentially of hydrogen (H₂) and argon (Ar). In one or more embodiments, the second plasma consists of hydrogen (H₂) and argon (Ar).

In one or more embodiments, the second plasma comprises ammonia (NH₃), hydrogen (H₂), and argon (Ar). In one or more embodiments, the second plasma consists essentially of ammonia (NH₃), hydrogen (H₂), and argon (Ar). In one or more embodiments, the second plasma consists of ammonia (NH₃), hydrogen (H₂), and argon (Ar).

In one or more embodiments, the second plasma comprises one or more of ammonia (NH₃) or hydrogen (H₂), nitrogen (N₂), and argon (Ar).

In one or more embodiments, the second plasma comprises ammonia (NH₃), nitrogen (N₂), and argon (Ar). In one or more embodiments, the second plasma consists essentially of ammonia (NH₃), nitrogen (N₂), and argon (Ar). In one or more embodiments, the second plasma consists of ammonia (NH₃), nitrogen (N₂), and argon (Ar).

In one or more embodiments, the second plasma comprises hydrogen (H₂), nitrogen (N₂), and argon (Ar). In one or more embodiments, the second plasma consists essentially of hydrogen (H₂), nitrogen (N₂), and argon (Ar). In one or more embodiments, the second plasma consists of hydrogen (H₂), nitrogen (N₂), and argon (Ar).

In one or more embodiments, the second plasma comprises ammonia (NH₃), hydrogen (H₂), nitrogen (N₂), and argon (Ar). In one or more embodiments, the second plasma consists essentially of ammonia (NH₃), hydrogen (H₂), nitrogen (N₂), and argon (Ar). In one or more embodiments, the second plasma consists of ammonia (NH₃), hydrogen (H₂), nitrogen (N₂), and argon (Ar).

In one or more embodiments, the second plasma comprises one or more of ammonia (NH₃) or hydrogen (H₂), and helium (He).

In one or more embodiments, the second plasma comprises ammonia (NH₃) and helium (He). In one or more embodiments, the second plasma consists essentially of ammonia (NH₃) and helium (He). In one or more embodiments, the second plasma consists of ammonia (NH₃) and helium (He).

In one or more embodiments, the second plasma comprises hydrogen (H₂) and helium (He). In one or more embodiments, the second plasma consists essentially of hydrogen (H₂) and helium (He). In one or more embodiments, the second plasma consists of hydrogen (H₂) and helium (He).

In one or more embodiments, the second plasma comprises ammonia (NH₃), hydrogen (H₂), and helium (He). In one or more embodiments, the second plasma consists essentially of ammonia (NH₃), hydrogen (H₂), and helium (He). In one or more embodiments, the second plasma consists of ammonia (NH₃), hydrogen (H₂), and helium (He).

In one or more embodiments, the second plasma comprises one or more of ammonia (NH₃) or hydrogen (H₂), nitrogen (N₂), and helium (He).

In one or more embodiments, the second plasma comprises ammonia (NH₃), nitrogen (N₂), and helium (He). In one or more embodiments, the second plasma consists essentially of ammonia (NH₃), nitrogen (N₂), and helium (He). In one or more embodiments, the second plasma consists of ammonia (NH₃), nitrogen (N₂), and helium (He).

In one or more embodiments, the second plasma comprises hydrogen (H₂), nitrogen (N₂), and helium (He). In one or more embodiments, the second plasma consists essentially of hydrogen (H₂), nitrogen (N₂), and helium (He). In one or more embodiments, the second plasma consists of hydrogen (H₂), nitrogen (N₂), and helium (He).

In one or more embodiments, the second plasma comprises ammonia (NH₃), hydrogen (H₂), nitrogen (N₂), and helium (He). In one or more embodiments, the second plasma consists essentially of ammonia (NH₃), hydrogen (H₂), nitrogen (N₂), and helium (He). In one or more embodiments, the second plasma consists of ammonia (NH₃), hydrogen (H₂), nitrogen (N₂), and helium (He).

Without intending to be bound by theory, it is thought that the second plasma comprising one or more of ammonia (NH₃) or hydrogen (H₂) removes surface atoms from the silicon-containing precursor, such as, for example, hydrogen atoms and/or chlorine atoms, and produces a NH-terminated surface, resulting in increased GPC.

In one or more embodiments, the third plasma comprises nitrogen (N₂). In one or more embodiments, the third plasma consists essentially of nitrogen (N₂). In one or more embodiments, the third plasma consists of nitrogen (N₂).

In one or more embodiments, the third plasma comprises nitrogen (N₂) and argon (Ar). In one or more embodiments, the third plasma consists essentially of nitrogen (N₂) and argon (Ar). In one or more embodiments, the third plasma consists of nitrogen (N₂) and argon (Ar).

In one or more embodiments, the third plasma comprises nitrogen (N₂) and helium (He). In one or more embodiments, the third plasma consists essentially of nitrogen (N₂) and helium (He). In one or more embodiments, the third plasma consists of nitrogen (N₂) and helium (He). In one or more embodiments, the first plasma and the third plasma have the same composition.

Without intending to be bound by theory, it is thought that the third plasma comprising nitrogen (N₂) improves thickness non-uniformity of the silicon nitride (SiₓN_{y}) film. It has been advantageously found that exposing each location on the substrate surface to the same amount of time to the first plasma including nitrogen (N₂) and third plasma including nitrogen (N₂) and the second plasma including one or more of ammonia (NH₃) or hydrogen (H₂), the thickness non-uniformity of the silicon nitride (SiₓN_{y}) film is improved compared to current PEALD approaches.

In some embodiments, the substrate is exposed to the first plasma for a time period in a range of from 100 milliseconds to 5 seconds. In some embodiments, the substrate is exposed to the second plasma for a time period in a range of from 100 milliseconds to 3 seconds. In some embodiments, the substrate is exposed to the third plasma for a time period in a range of from 10 milliseconds to 1 second.

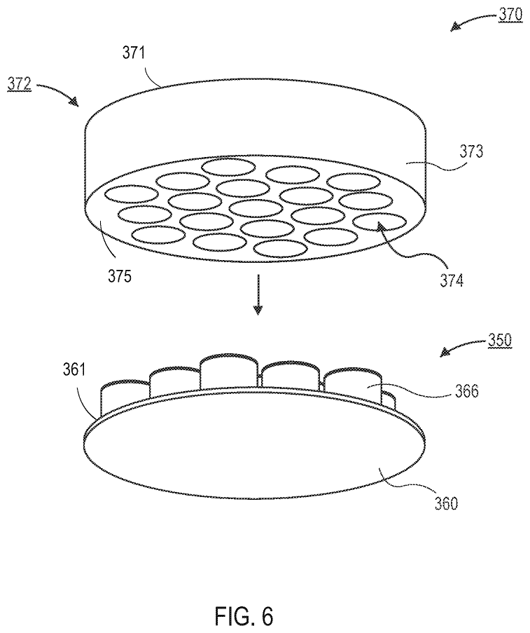

As will be described in further detail below with respect to FIG. 6, one or more embodiments are directed to a plasma showerhead assembly, e.g., an assembly 370 for a processing tool. In one or more embodiments, the assembly comprises a conductive plate and a dielectric faceplate.

In one or more embodiments, the conductive plate includes a first surface and a second surface opposite to the first surface defining a conductive plate thickness, a plurality of resonator openings extending from the first surface through the conductive plate to the second surface of the conductive plate, gas channels within the conductive plate thickness, a plurality of conductive plate gas openings on the second surface of the conductive plate in fluid communication with the gas channels within the conductive plate thickness.

In one or more embodiments, the dielectric faceplate comprises a first surface and a second surface opposite to the first surface defining a dielectric faceplate thickness, a plurality of dielectric resonator protruding from the first surface and configured so that the resonators fit into the plurality of the resonator openings of the conductive plate when assembled, each resonator having a geometric center; and a plurality of dielectric faceplate gas openings extending through the dielectric faceplate thickness.

In one or more embodiments, the substrate 50 is not purged between the second plasma exposure and the third plasma exposure. During the gas transition from the first plasma including nitrogen (N₂) to the second plasma including one or more of ammonia (NH₃) or hydrogen (H₂), at the substrate surface under the plurality of dielectric faceplate gas openings, e.g., the gas openings nearest to the substrate, the plasma species reaches steady state faster than locations not directly under the plurality of dielectric faceplate gas openings, and decays faster than those locations not directly under the plurality of dielectric faceplate gas openings. The third plasma exposure with short period time is used to compensate the gas transition speed difference on each location on the substrate, so each location on the substrate has the same amount of exposure time to the second plasma including one or more of ammonia (NH₃) or hydrogen (H₂). Advantageously, where the substrate 50 is not purged between the second plasma exposure and the third plasma exposure and each location on the substrate has the same amount of exposure time to the second plasma including one or more of ammonia (NH₃) or hydrogen (H₂), the thickness non-uniformity of the silicon nitride (SiₓN_{y}) film 54 is improved, e.g., the thickness non-uniformity is less than or equal to 3%, less than or equal to 2%, less than or equal to 1.5%, or less than or equal to 1%.

Embodiments of the disclosure advantageously provides methods of depositing a silicon nitride (SiₓN_{y}) film at an increased growth rate per cycle (GPC). Some embodiments, advantageously provide methods of depositing a silicon nitride (SiₓN_{y}) film having a low amount of thickness non-uniformity in the film. As used herein, “thickness non-uniformity” refers to the amount of variation in thickness of the film across the substrate which the film is deposited on. Embodiments of the disclosure advantageously provide a SiₓN_{y} film that has a reduced etch amount in Angstroms (Å) using dilute HF 100:1, which represents an improved wet etch rate, compared to a current PEALD approaches.

For example, current PEALD approaches: (1) exposure to silicon-containing precursor, purge, exposure to thermal ammonia (NH₃), followed by nitrogen (N₂) plasma, or (2) exposure to silicon-containing precursor, purge, exposure to ammonia (NH₃) plasma, and purge, each independently produce films of poor quality and reduced GPC.

One of the most common metrics used to measure SiₓN_{y} film quality is the wet etch rate of the deposited film under dilute hydrofluoric (HF) acid etch solution, such as dilute HF 100:1.

In the first (1) current PEALD approach, for example, the silicon nitride (SiₓN_{y}) film has a growth rate of less than 0.5 Å/cycle, a thickness non-uniformity of about 12%, and an etch amount of greater than or equal to 3 Å. In the second (2) current PEALD approach, for example, the silicon nitride (SiₓN_{y}) film has a thickness non-uniformity of about 5%, and an etch amount of greater than or equal to 2.8 Å.

In one or more embodiments, the silicon nitride (SiₓN_{y}) film grows at a rate of greater than or equal to 0.5 Å/cycle. In one or more embodiments, the silicon nitride (SiₓN_{y}) film grows at a rate of greater than or equal to 0.7 Å/cycle. In one or more embodiments, the silicon nitride (SiₓN_{y}) film has a thickness non-uniformity of less than or equal to 4%. In one or more embodiments, the silicon nitride (SiₓN_{y}) film has a thickness non-uniformity of less than or equal to 3%, less than or equal to 2%, less than or equal to 1.5%, or less than or equal to 1%. In one or more embodiments, the silicon nitride (SiₓN_{y}) film advantageously has an etch amount of less than or equal to 2.5 Å.

The first plasma, the second plasma, and the third plasma may be independently generated by any suitable plasma source. In one or more embodiments, a remote plasma source, an inductively coupled plasma (ICP) source, a capacitively coupled plasma (CCP) source, or a microwave plasma source may be used to generate the first plasma, the second plasma, and/or the third plasma.

The skilled artisan will appreciate that any remote plasma source, inductively coupled plasma (ICP) source, capacitively coupled plasma source (CCP) source, or microwave plasma source that is suitable for generating the first plasma, the second plasma, and/or the third plasma may be implemented for the disclosed methods.

One or more embodiments of the present disclosure include modular microwave plasma processing tools. Modular microwave plasma sources have a high plasma density and very low plasma potential (e.g., less than or equal to 10 eV).

In some embodiments, the first plasma is a microwave plasma generated by a microwave plasma source, including, but not limited to, the microwave plasma sources described herein. In some embodiments, the second plasma is a microwave plasma generated by a microwave plasma source, including, but not limited to, the microwave plasma sources described herein. In some embodiments, the third plasma is a microwave plasma generated by a microwave plasma source, including, but not limited to, the microwave plasma sources described herein. In one or more embodiments, each of the first plasma, the second plasma, and the third plasma is a microwave plasma generated by the microwave plasma sources described herein.

In one or more embodiments, the plasma source used to generate the third plasma is turned on after the plasma source used to generate the second plasma is turned off with a time delay of 0 seconds. Stated differently, turn on of the third plasma follows the second plasma with 0 second time delay. In one or more embodiments, the plasma source used to generate the third plasma is turned on after the plasma source used to generate the second plasma is turned off with a time delay of about 0.1 seconds. In one or more embodiments, the plasma source used to generate the third plasma is turned on after the plasma source used to generate the second plasma is turned off with a time delay of about 0.2 seconds. In one or more embodiments, the plasma source used to generate the third plasma is turned on after the plasma source used to generate the second plasma is turned off with a time delay of about 0.3 seconds. In one or more embodiments, the plasma source used to generate the third plasma is turned on after the plasma source used to generate the second plasma is turned off with a time delay of about 0.4 seconds. In one or more embodiments, the plasma source used to generate the third plasma is turned on after the plasma source used to generate the second plasma is turned off with a time delay of about 0.5 seconds.

It has been advantageously found that where the plasma source used to generate the third plasma is turned on after the plasma source used to generate the second plasma is turned off with a time delay of greater than or equal to 0.2 seconds, such as in a range of from 0.2 seconds to 0.5 seconds, the thickness non-uniformity of the silicon nitride (SiₓN_{y}) film 54 is less than or equal to 3%, less than or equal to 2%, less than or equal to 1.5%, or less than or equal to 1%.

The method 10 may be performed at any suitable processing conditions, and the processing conditions may vary depending upon the application for which the silicon nitride (SiₓN_{y}) film is formed.

In some embodiments, the method 10 is performed at relatively low temperatures. The relative low temperatures advantageously result in decreased damage to surrounding materials (e.g., dielectrics). In some embodiments, the method 10 is performed at a temperature in the range of 20° C. to 600° C. Stated differently, “the method 10 is performed at a temperature in the range of 20° C. to 600° C.” means that the semiconductor processing chamber in which the method 10 is performed is maintained at a temperature in the range of 20° C. to 600° C. In some embodiments, the method 10 is performed at a temperature in the range of 100° C. to 600° C.

In some embodiments, the method 10 is performed at a pressure in a range of from 0.1 Torr to 20 Torr. Stated differently, “the method 10 is performed at a pressure in a range of from 0.1 Torr to 20 Torr” means that the semiconductor processing chamber in which the method 10 is performed is maintained at a pressure in a range of from 0.1 Torr to 20 Torr. In some embodiments, the method 10 is performed at a temperature in the range of 0.1 Torr to 1 Torr.

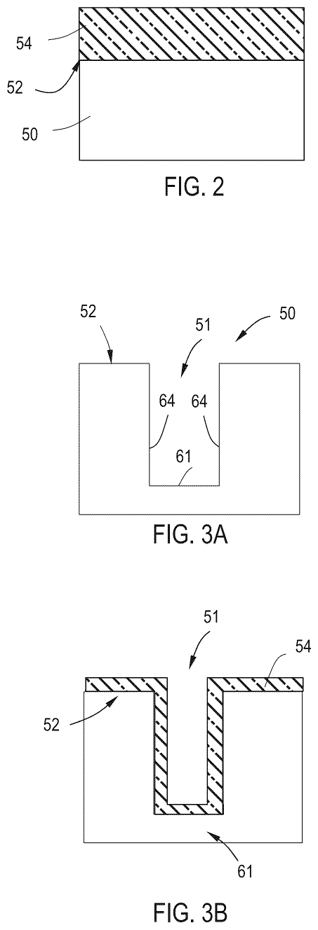

FIG. 2 illustrates a cross-sectional schematic view of a substrate 50. FIGS. 3A-3B also illustrate cross-sectional schematic views of the substrate 50 according to one or more embodiments of the disclosure. The substrate 50 can be any suitable substrate material. In one or more embodiments, the substrate 50 comprises a semiconductor material, e.g., any metal material, silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), a high-κ dielectric material other semiconductor materials, or any combination thereof. In one or more embodiments, the substrate 50 comprises one or more of silicon (Si), germanium (Ge), gallium (Ga), arsenic (As), indium (In), phosphorus (P), or selenium (Se). Although a few examples of materials from which the substrate 50 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) may can be utilized.

In some embodiments, the substrate 50 may include dielectric materials, for example, silicon-containing dielectric materials and/or metal oxide dielectric materials. In some embodiments, the substrate 50 may comprise one or more dielectric surfaces comprising a low-κ dielectric material such as, but not limited to, silicon oxide (SiOx), silicon sub-oxides, silicon nitride (SiₓN_{y}), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof.

In FIGS. 2 and 3A-3B, the SiₓN_{y} film 54 is formed on a top surface 52 of the substrate 50. In accordance with the method 10, at decision point 19, the substrate 50 is evaluated to determine whether or not the silicon nitride (SiₓN_{y}) film 54 has reached a predetermined thickness or a predetermined number of cycles have been performed. In some embodiments, the SiₓN_{y} film 54 has a thickness in a range of from about 0.5 nm to about 30 nm. In some embodiments, the SiₓN_{y} film 54 has a thickness in a range of from about 1 nm to about 8 nm.

Further aspects of the disclosure pertain to a method that is part of a gap fill process. The disclosed methods may be utilized with any device nodes, but may be particularly advantageous in device nodes of about 25 nm or less, for example about 5nm to about 25 nm. In some embodiments, a SiₓN_{y} film 54 is deposited on a dielectric surface with one or more high aspect ratio gap features, including vertical gap features and/or horizontal gap features, and the SiₓN_{y} film 54 in the gap features forms horizontal interconnects through which current flows.

FIGS. 3A-3B illustrate schematic cross-sectional views of a deposition process on the substrate 50 including at least one feature 51 that has a gap defined by a top surface 52, two opposed sidewalls 64, and a bottom surface 61. The two opposed sidewalls 64 may comprise any suitable material. In one or more embodiments, the two opposed sidewalls 64 comprise a dielectric material, e.g., a low-κ dielectric material such as, but not limited to, silicon oxide (SiOx), silicon sub-oxides, silicon nitride (SiₓN_{y}), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof. The bottom surface 61 may comprise any suitable material, such as a metallic material.

In FIG. 3A, the substrate 50 is shown having a single feature 51. Referring to FIG. 3B, in one or more embodiments, a conformally deposited SiₓN_{y} film 54 is shown directly on the top surface 52 and along the two opposed sidewalls 64 and the bottom surface 61.

The Figures show the substrate 50 having a single feature 51 for illustrative purposes; however, those skilled in the art will understand that there can be more than one feature 51. The shape of the feature 51 can be any suitable shape including, but not limited to, trenches and cylindrical vias, as described herein.

In one or more embodiments, the at least one feature 51 comprises one or more of a trench or a via. In specific embodiments, the at least one feature 51 comprises a trench. In still further embodiments, the term “at least one feature 51” and “trench 51” may be used interchangeably. The trench 51 has a depth to the bottom surface 61 and a width between the two opposed sidewalls 64. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In one or more embodiments, the aspect ratio of the trench 51 described herein is greater than or equal to about 1:1, 2:1, 5:1, 10:1,15:1, 20:1, 25:1, 30:1, 35:1, or 40:1.

It will be appreciated by the skilled artisan that the method that is part of a gap fill process can include one or more subsequent operations after forming the SiₓN_{y} film 54, such as, for example, filling the gap with a conductive material, to form an interconnect, and that the one or more subsequent operations can be performed without undue experimentation.

The methods described herein may be performed in any suitable processing chamber known to the skilled artisan. The methods described herein may be performed in, for example, a PEALD processing chamber.

Embodiments of the disclosure are directed to processing tools. In some embodiments, the processing tool comprises: a central transfer station comprising a robot configured to move a semiconductor, a plurality of process stations, and a controller connected to the central transfer station and the plurality of process stations. In some embodiments, each process station is connected to the central transfer station and provides a processing region separated from processing regions of adjacent process stations. In some embodiments, the plurality of process stations comprises a plasma-enhanced atomic layer deposition (PEALD) chamber. In some embodiments, the controller is configured to activate the robot to move the wafer between process stations, and to control a processing method, such as method 10, and form a SiₓN_{y} film on a substrate.

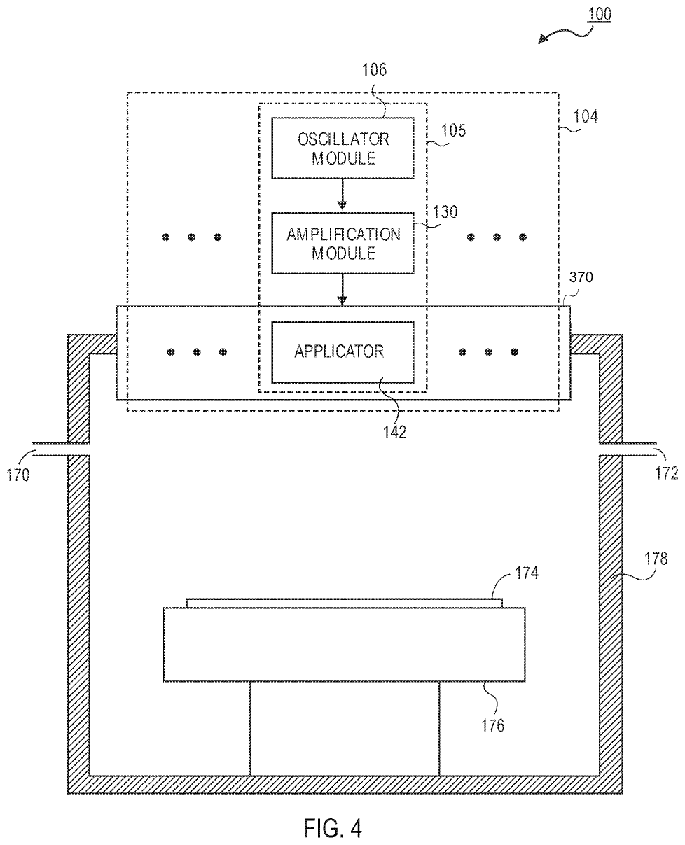

In accordance with one or more embodiments, FIG. 4 illustrates a schematic representation of a processing tool 100. In some embodiments, the processing tool 100 may be a processing tool suitable for any type of processing operation that utilizes a plasma. For example, the processing tool 100 may be a processing tool used for plasma enhanced chemical vapor deposition (PECVD), plasma-enhanced atomic layer deposition (PEALD), etch and selective removal processes, and plasma cleaning. In one or more embodiments, the processing tool 100 is used for plasma-enhanced atomic layer deposition (PEALD) of silicon nitride (SiₓN_{y}) according to the methods described herein, e.g., method 10.

The processing tool 100 includes a semiconductor processing chamber 178. In one or more embodiments, the semiconductor processing chamber 178 is a vacuum chamber. In one or more unillustrated embodiments, the vacuum chamber may include a pump for removing gases from the chamber to provide the desired vacuum. Additional embodiments may include a semiconductor processing chamber 178 that includes one or more gas lines 170 for providing processing gasses into the semiconductor processing chamber 178 and exhaust lines 172 for removing byproducts from the semiconductor processing chamber 178. While not shown, it is to be appreciated that gas may also be injected into the semiconductor processing chamber 178 through the assembly 370 for evenly distributing the processing gases over a substrate 174.

In one or more embodiments, the substrate 174 is supported on a chuck 176. For example, the chuck 176 may be any suitable chuck, such as an electrostatic chuck. The chuck 176 may also include cooling lines and/or a heater to provide temperature control to the substrate 174 during processing. Due to the modular configuration of the high-frequency emission modules described herein, embodiments allow for the processing tool 100 to accommodate any sized substrate 174. For example, the substrate 174 may be a semiconductor wafer (e.g., 200 mm, 300 mm, 450 mm, or larger). Alter-native embodiments also include substrates 174 other than semiconductor wafers. For example, embodiments may include a processing tool 100 configured for processing glass substrates, (e.g., for display technologies).

In one or more embodiments, the processing tool 100 includes a modular high-frequency emission source 104. The modular high-frequency emission source 104 includes an array of high-frequency emission modules 105. In one or more embodiments, each high-frequency emission module 105 independently includes an oscillator module 106, an amplification module 130, and an applicator 142. The oscillator module 106 may include a plurality of oscillator modules 106. The applicators 142 are schematically shown as being integrated into the dielectric faceplate 350. The skilled artisan will appreciate that the disclosure is not limited to the applicators 142 being integrated into the assembly 370.

In one or more embodiments, the oscillator module 106 and the amplification module 130 may comprise electrical components that are solid state electrical components. In one or more embodiments, each of the plurality of oscillator modules 106 are independently communicatively coupled to different amplification modules 130. In some embodiments there may be a 1:1 ratio between oscillator modules 106 and amplification modules 130. For example, each oscillator module 106 may be electrically coupled to a single amplification module 130.

In one or more embodiments, each oscillator module 106 independently generates high-frequency electromagnetic radiation that is transmitted to the amplification module 130. After processing by the amplification module 130, the electromagnetic radiation is transmitted to the applicator 142. In one or more embodiments, the applicators 142 each emit electromagnetic radiation into the semiconductor processing chamber 178.

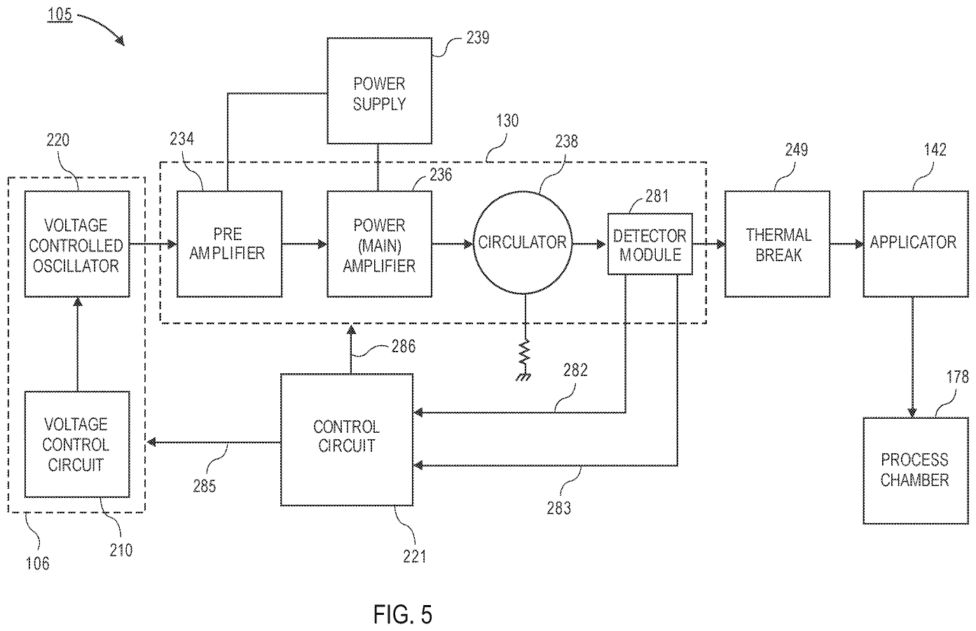

FIG. 5 illustrates a block diagram of a high-frequency emission module 105. In one or more embodiments, the high-frequency emission module 105 comprises the plurality of oscillator modules 106. Each oscillator module 106 may independently include a voltage control circuit 210 for providing an input voltage to a voltage controlled oscillator 220 in order to produce high-frequency electromagnetic radiation at a desired frequency. One or more embodiments include an input voltage in a range of from 1 V to 10V of DC. In one or more embodiments, the voltage controlled oscillator 220 is an electronic oscillator whose oscillation frequency is controlled by the input voltage. According to one or more embodiments, the input voltage from the voltage control circuit 210 results in the voltage controlled oscillator 220 oscillating at a desired frequency. In some embodiments, the high-frequency electromagnetic radiation has a frequency in a range of from about 0.1 MHz to about 30 MHz. In some embodiments, the high-frequency electromagnetic radiation has a frequency in a range of from about 30 MHz to about 300 MHz. In some embodiments, the high-frequency electromagnetic radiation has a frequency in a range of from about 300 MHz to about 1 GHz. In some embodiments, the high-frequency electromagnetic radiation has a frequency in a range of from about 1 GHz to about 300 GHz.

According to one or more embodiments, the electromagnetic radiation is transmitted from the voltage controlled oscillator 220 to the amplification module 130. The amplification module 130 may include a driver/pre-amplifier 234 and a main power amplifier 236, and each of the driver/pre-amplifier 234 and the main power amplifier 236 are independently coupled to a power supply 239. According to one or more embodiments, the amplification module 130 may operate in a pulse mode. For example, the amplification module 130 may have a duty cycle in a range of from 1% to 99%. In specific embodiments, the amplification module 130 may have a duty cycle in a range of from 15% to 50%.

In some embodiments, the electromagnetic radiation may be transmitted to the thermal break 249 and the applicator 142 after being processed by the amplification module 130. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. The skilled artisan will appreciate that the detector module 281 may be located at one or more different locations in the system (e.g., between the circulator 238 and the thermal break 249). In some embodiments, the control circuit module 221 interprets the forward power 283 and the reflected power 282, and determines the level for the control signal 285 that is communicatively coupled to the oscillator module 106 and the level for the control signal 286 that is communicatively coupled to the amplification module 130. In some embodiments, control signal 285 adjusts the oscillator module 106 to optimize the high-frequency radiation coupled to the amplification module 130. In some embodiments, control signal 286 adjusts the amplification module 130 to optimize the output power coupled to the applicator 142 through the thermal break 249.

Accordingly, one or more embodiments allow for an increased percentage of the forward power to be coupled into the semiconductor processing chamber 178, and increases the available power. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 220.

In some embodiments, a total delivered power from the microwave source is equal to level of forward power 283 minus the level of reflected power 282. In some embodiments, the total delivered power from microwave source is in a range of about 2300 Watts (W) to about 3800 Watts (W), such as, for example, 3325 Watts (W).

Referring now to FIG. 6, a schematic exploded perspective view of the assembly 370 is shown. The assembly 370 comprises a conductive plate 372 and a dielectric faceplate 350. As indicated by the arrow, the conductive plate 372 fits over and around the dielectric faceplate 350. In the illustrated embodiment, the assembly 370 is shown as having a substantially circular shape. However, the skilled artisan will appreciate that the assembly 370 may have any suitable shape such as polygonal, elliptical, wedge shaped, or the like.

The conductive plate 372 comprises a conductive body 373 including a first surface 371 and a second surface 375 opposite to the first surface defining a conductive plate thickness, a plurality of resonator openings 374 extending from the first surface 371 through the conductive plate 372 to the second surface 375 of the conductive plate 372, gas channels within the conductive plate thickness, a plurality of conductive plate gas openings on the second surface 375 of the conductive plate 372 in fluid communication with the gas channels within the conductive plate thickness.

In some embodiments, the dielectric faceplate 350 comprises a first surface 361 and a second surface 360 opposite to the first surface 361 defining a dielectric faceplate thickness, a plurality of dielectric resonators 366 protruding from the first surface 361 and configured so that the resonators 366 fit into the plurality of the resonator openings 374 of the conductive plate 372 when assembled, each resonator 366 having a geometric center; and a plurality of dielectric faceplate gas openings extending through the dielectric faceplate thickness.

The conductive body 373 may include any suitable conductive material. For example, the conductive body 373 may be aluminum or the like. The plurality of resonator openings 374 may pass entirely through a thickness of the conductive body 373. The resonator openings 374 may be sized to receive the dielectric resonators 366. For example, as the conductive plate 372 is displaced towards the dielectric faceplate 350 (as indicated by the arrow in FIG. 6) the dielectric resonators 366 will be inserted into the plurality of resonator openings 374.

In the illustrated embodiment of FIG. 6, the conductive plate 372 is shown as a single conductive body 373. However, the skilled artisan will appreciate that the conductive plate 372 may comprise one or more discrete conductive components. The discrete components may be individually grounded, or the discrete components may be joined mechanically or by any form of metallic bonding, to form a single electrically conductive body 373.

In some embodiments, the dielectric faceplate 350 and the plurality of dielectric resonators 366 are a monolithic structure. That is, in embodiments where the dielectric faceplate 350 and the plurality of dielectric resonators 366 are a monolithic structure, there is no physical interface between a bottom of the dielectric resonators 366 and the dielectric faceplate 350. As used herein, a “physical interface” refers to a first surface of a first discrete body contacting a second surface of a second discrete body.

In other embodiments, the dielectric faceplate 350 and the dielectric resonators 366 are discrete components. Each of the dielectric resonators 366 are a portion of the applicator 142 used to inject high-frequency electromagnetic radiation into a processing chamber, such as the semiconductor processing chamber 178.

In some embodiments, the dielectric faceplate 350 comprises a dielectric material. For example, the dielectric faceplate 350 may be a ceramic material. In some embodiments, one suitable ceramic material that may be used for the dielectric faceplate 350, as an example, is aluminum oxide (Al₂O₃). In specific embodiments where the dielectric faceplate 350 and the plurality of dielectric resonators 366 are a monolithic structure, the monolithic structure may be fabricated from a single block of material. In other embodiments, a rough shape of the dielectric faceplate 350 may be formed with a molding process, and subsequently machined to provide the final structure with the desired dimensions. For example, green state machining and firing may be used to provide the desired shape of the dielectric faceplate 350. In the illustrated embodiment, the dielectric resonators 366 are shown as having a circular cross-section (when viewed along a plane parallel to the dielectric faceplate 350). However, the skilled artisan will appreciate that the dielectric resonators 366 may comprise many different cross-sections. For example, the cross-section of the dielectric resonators 366 may have any shape that is centrally symmetric.

In one or more unillustrated embodiments, the dielectric faceplate 350 includes one or more rings configured to separate the sidewall of the plurality of resonator openings 374 in the conductive plate 372 from the sidewall of the dielectric resonator 366. The rings may be electrically coupled to the conductive body 373 and are grounded during operation of the processing tool. Accordingly, the entire length of the sidewall is covered by a grounded surface. It has been advantageously found that covering the entire length of the sidewall with a grounded surface improves the resonance characteristics of the dielectric faceplate 350, and provides improved coupling of the high-frequency electromagnetic radiation into the processing chamber, such as semiconductor processing chamber 178.

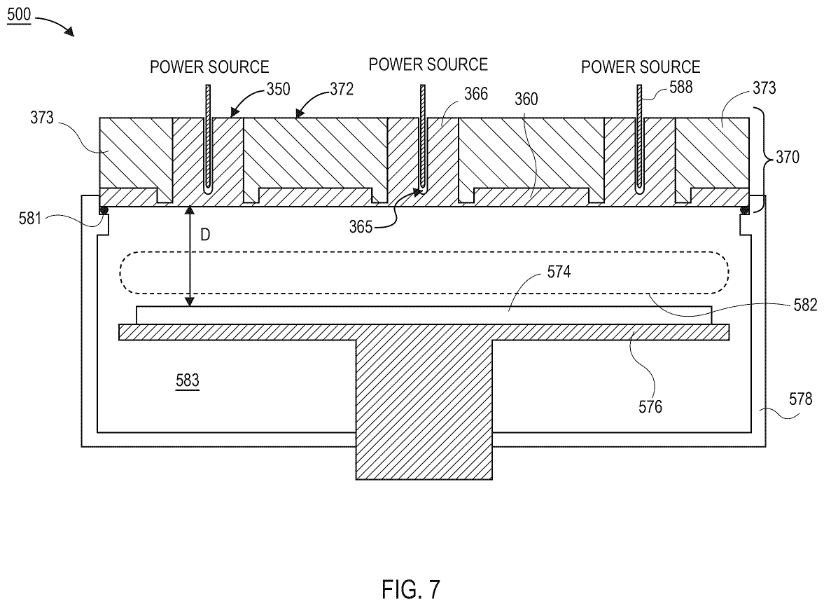

FIG. 7 illustrates a cross-sectional view of a processing tool 500 according to one or more embodiments. In one or more embodiments, the processing tool 500 comprises a semiconductor processing chamber 578 that is sealed by the assembly 370. For example, the assembly 370 may rest against one or more o-rings 581 to provide a vacuum seal to an interior volume 583 of the semiconductor processing chamber 578.

In one or more embodiments, the plurality of o-rings 581 surrounding the conductive plate gas openings and the dielectric faceplate gas openings, and the dielectric faceplate gas openings are in fluid communication with the conductive plate gas openings and the o-rings 581 are configured to seal the dielectric faceplate gas openings and the conductive plate gas openings from atmospheric pressure. In other embodiments, the assembly 370 may interface with the semiconductor processing chamber 578. That is, the assembly 370 may be part of a lid that seals the semiconductor processing chamber 578. In some embodiments, the processing tool 500 may comprise a plurality of processing volumes (which may be fluidically coupled together), with each processing volume independently having an assembly, such as, for example, the assembly 370.

In some embodiments, a chuck 576 or the like may support a workpiece 574 (e.g., wafer, substrate, etc.). In one or more embodiments, the assembly 370 is spaced a distance D from the workpiece 574. The distance D may be any suitable distance. In some embodiments, the chamber interior volume 583 may be suitable for striking a plasma 582. That is, the semiconductor processing chamber 578 may be a vacuum chamber.

In some embodiments, monopole antennas 588 may extend into holes 365 in the dielectric resonators 366. The monopole antennas 588 are each electrically coupled to power sources (e.g., high-frequency emission modules 105).

In one or more embodiments, the substrate 50 is the substrate 174 in the processing tool 100. In one or more embodiments, the substrate 50 is the workpiece 574 in the processing tool 500. The methods of depositing the SiₓN_{y} film described herein, e.g., the method 10 may be implemented in any of the processing tools described herein.

One or more embodiments of the disclosure are directed to a non-transitory computer readable medium including instructions, that, when executed by a controller of a processing chamber, cause the processing chamber to perform the operations of method 10.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing a silicon nitride (SiₓN_{y}) film, the method comprising:
exposing a substrate in a semiconductor processing chamber to a silicon-containing precursor;
exposing the substrate to a first plasma including nitrogen (N₂);
exposing the substrate to a second plasma including one or more of ammonia (NH₃) or hydrogen (H₂); and
exposing the substrate to a third plasma including nitrogen (N₂).

2. The method of claim 1, comprising repeating one or more operations of the method to deposit the silicon nitride (SiₓN_{y}) film to a predetermined thickness.

3. The method of claim 1, wherein the first plasma comprises nitrogen (N₂) and argon (Ar).

4. The method of claim 1, wherein the first plasma comprises nitrogen (N₂) and helium (He).

5. The method of claim 1, wherein the second plasma further comprises argon (Ar).

6. The method of claim 1, wherein the second plasma further comprises nitrogen (N₂) and argon (Ar).

7. The method of claim 1, wherein the second plasma further comprises helium (He).

8. The method of claim 1, wherein the second plasma further comprises nitrogen (N₂) and helium (He).

9. The method of claim 1, wherein the third plasma comprises nitrogen (N₂) and argon (Ar).

10. The method of claim 1, wherein the third plasma comprises nitrogen (N₂) and helium (He).

11. The method of claim 1, wherein the substrate is exposed to the first plasma for a time period in a range of from 100 milliseconds to 5 seconds.

12. The method of claim 1, wherein the substrate is exposed to the second plasma for a time period in a range of from 100 milliseconds to 3 seconds.

13. The method of claim 1, wherein the substrate is exposed to the third plasma for a time period in a range of from 10 milliseconds to 1 second.

14. The method of claim 1, wherein each of the first plasma, the second plasma, and the third plasma is independently generated by a plasma source comprising one or more of a remote plasma source, an inductively coupled plasma (ICP) source, a capacitively coupled plasma (CCP) source, or a microwave plasma source.

15. The method of claim 14, wherein each of the first plasma, the second plasma, and the third plasma independently comprises a microwave plasma generated by the microwave plasma source.

16. The method of claim 14, wherein the plasma source used to generate the third plasma is turned on after the plasma source used to generate the second plasma is turned off with a time delay of 0 seconds.

17. The method of claim 1, wherein the silicon nitride (SiₓN_{y}) film grows at a rate of greater than or equal to 0.5 Å/cycle.

18. The method of claim 1, wherein the substrate is not purged between exposure to the second plasma and exposure to the third plasma.

19. The method of claim 1, performed at a temperature in a range of from 100° C. to 600° C.

20. The method of claim 1, performed at a pressure in a range of from 0.1 Torr to 20 Torr.
